(19) United States
(12) Patent Application Publication
(10) Pub. No.: US 2005/0196898 A1
(43) Pub. Date: Sep. 8, 2005

(54) Process of plating through hole

(76) Inventors: Kwun-Yao Ho, Hsin-Tien City (TW); Moriss Kung, Hsin-Tien City (TW)

Correspondence Address: J C PATENTS, INC., 4 VENTURE, SUITE 250, IRVINE, CA, 92618, US

(21) Appl. No.: 11/065,496

(22) Filed: Feb. 23, 2005

(30) Foreign Application Priority Data
Mar. 2, 2004 (TW) 93105346

(51) Int. Cl. H01L 21/44; H01L 21/48

(52) U.S. Cl. 438/108

(57) ABSTRACT

A process of plating through hole is provided. First, a through hole is formed on a substrate. The through hole is connected to a first surface and a second surface of the substrate. Next, a photoresist layer is formed on the inner wall of the through hole, the first surface and the second surface. Thereafter, a plurality of grooves is formed on the photoresist layer such that each groove extends from the first surface to the second surface through the inner wall of the through hole. Thus, a portion of the first surface, the inner wall of the through hole and the second surface are exposed by the grooves. A conductive material is deposited into each groove to form a conductive line. Finally, the photoresist layer is removed to produce a through hole having multiple conductive lines.

### CROSS-REFERENCE TO RELATED APPLICATION

This application claims the priority benefit of Taiwan application serial No. 93105346, filed on Mar. 2, 2004.

### BACKGROUND OF THE INVENTION

1. Field of the Invention

The present invention relates to a process of plating through hole. More particularly, the present invention relates to a process of fabricating multiple conductive lines within a single through hole.

2. Description of Related Art

With rapid progress in electronic technologies, many multifunctional electronic products have been developed. As the process of fabricating semiconductor devices continue to improve, a higher level of integration for semiconductor devices is attained. To produce a chip package having a higher level of complexity but a smaller size, techniques for forming various types of packages such as flip chip (FC) packages, ball grid array (BGA) packages and chip scale packages have been developed. On the other hand, a build-up or lamination method can be used to produce a multi-layered printed circuit board (PCB) having a high circuit density. The high circuit density PCB may serve as a packaging substrate for the aforementioned flip-chip packages or the BGA packages. Typically, the multi-layered circuit board or the packaging substrate has a plurality of plated through holes for connecting the signaling lines on different patterned circuit layers.

FIGS. 1A through 1D are schematic cross-sectional views showing a conventional process for plating through holes. First, as shown in FIG. 1A, a substrate 100 having a copper film 102 formed on an upper and a lower surface of the substrate 100 is provided. A through hole 104 is formed in the substrate 100 by laser drilling or mechanical drilling, for example. As shown in FIG. 1B, a copper plating process is carried out to form a copper layer 110 over the copper films 102 and the inner sidewall of the through hole 104. As shown in FIG. 1C, the through hole 104 is plugged by putting ink into the hole 104 in a printing process. After plugging the through hole 104, moisture is prevented from getting into the hole 104 to induce the so-called popcorn effect.

After the aforementioned plating process, the copper film 110 is patterned. First, a photolithographic process that includes photoresist coating, photo-exposure and chemical development of the exposed photoresist layer is carried out to form a patterned photoresist layer. Thereafter, using the patterned photoresist layer as an etching mask, the copper film 110 is etched to form patterned circuit layers 110a, 110b on the upper and lower surface of the substrate 100 and obtained a single layer circuit board 150 as shown in FIG. 1D. As shown in FIG. 1D, the patterned circuit layers 110a and 110b on the upper and lower surface of the substrate 100 are electrically connected through the conductive layer 110c. When the aforementioned plating process is applied to a multi-layered circuit board, two or more patterned circuit layers at different levels can be connected through the plated through holes so that signals can easily pass from one circuit layer to a different circuit layer. It should be noted that a portion of the surface in the substrate for laying wires is sacrificed after forming the through hole and associated land area. In addition, the through hole is also bounded below by a minimum diameter. Therefore, the design of through holes may affect the level of circuit integration critically.

In the aforementioned substrate design, each through hole only provides a single signal connection pathway. To fully utilize each through hole, a structure having multiple conductive lines has been developed. FIG. 2 is a perspective view showing a cutout portion of a conventional plated through hole with multiple conductive lines. After forming a conductive layer 210 on the inner wall of a through hole 220, a plurality of grooves 230 is formed in the conductive layer 210 by ablation with a laser beam 250. Hence, the conductive layer 210 is cut into a plurality of independent sub conductive layers 210a such that each of the sub conductive layers can carry a different connecting signal.

However, to ensure complete separation of neighboring sub conductive layers 210a after the laser cutting process, it is difficult to avoid damaging a portion of the substrate 200 just outside the copper layer 210. Furthermore, both the glass fiber layer (not shown) covering the substrate 200 and the copper layer 120 are materials that are not easy to remove with laser. Thus, a longer processing time or a stronger laser beam is required incurring higher production cost. In addition, the processing width of a laser beam 250 is quite narrow so that the grooves 230 produced by the laser beam 250 on the conductive layer 210 are narrow as well. Because the grooves 230 are narrow, ink 206 can hardly fill all the interior space and lead to the formation of voids inside the grooves 230. Ultimately, electrical performance and reliability of the entire circuit is affected.

### SUMMARY OF THE INVENTION

Accordingly, the present invention is directed to a process of plating through hole capable of producing multiple independent conductive lines inside a single through hole to provide multiple signal transmission.

According to an embodiment of the present invention, a process of plating through hole capable of producing multiple conductive lines in a single through hole is provided. First, a substrate having a first surface and a second surface is provided. Thereafter, a through hole that connects the first surface and the second surface of the substrate together is formed in the substrate. Next, a photoresist layer is formed over the substrate to cover the inner sidewall of the through hole, the first surface and the second surface. A plurality of grooves is formed in the photoresist layer such that each groove extends from the first surface to the second surface through the inner wall of the through hole. Furthermore, each groove exposes a portion of the inner wall of the through hole, a portion of the first surface and a portion of the second surface. Afterwards, a conductive material is deposited into the grooves to produce multiple conductive lines. The conductive lines extend from the first surface to the second surface through the inner wall of the through hole. Finally, the photoresist layer is removed to produce a single through hole having multiple independent conductive lines.

The present invention also directed to a second process of plating through hole capable of producing multiple conductive lines in a single through hole. First, a substrate having a first surface and a second surface is provided. Thereafter, a through hole that connects the first surface and the second surface of the substrate together is formed in the substrate. Next, a conductive layer is formed over the substrate to cover the inner wall of the through hole, the first surface and the second surface. A plurality of linear photoresist strips is formed over the conductive layer such that each linear photoresist strip extends from the first surface to the second surface through the inner wall of the through hole. Afterwards, a portion of the exposed conductive layer between the linear photoresist strips is removed to form a plurality of conductive lines that extends from the first surface to the second surface through the inner wall of the through hole. Finally, the photoresist layer is removed to produce a single through hole having multiple independent conductive lines.

Accordingly, the through hole according to an embodiment of the present invention can be fabricated in two alternative ways. A photolithographic process is carried out to form a patterned photoresist layer having a plurality of grooves over a substrate with a preformed through hole and then an electroplating process or deposition process is performed to form a plurality of conductive lines inside the grooves. Alternatively, metallic material is deposited to cover the entire surface of a substrate with a preformed through hole and then a portion of the metallic layer is removed using a patterned photoresist layer as an etching mask to form a plurality of conductive lines. In either way, the process of plating through hole involves a photolithographic process to form a patterned photoresist layer and an electroplating, deposition or etching process to form multiple conductive lines within a single through hole.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are schematic cross-sectional views showing a conventional process of plating through holes.

FIG. 2 is a perspective view showing a cutout portion of a conventional plated through hole with multiple conductive lines.

FIGS. 3A through 3F are partially cut perspective views showing the steps in a first process of plating through hole according to one embodiment of the present invention.

FIGS. 4A through 4G are partially cut perspective views showing the steps in a second process of plating through hole according to one embodiment of the present invention.

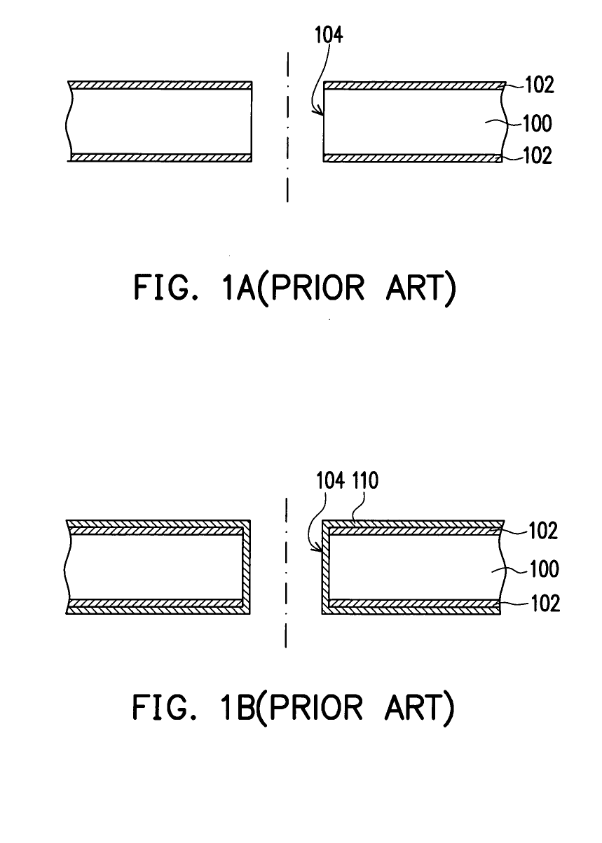

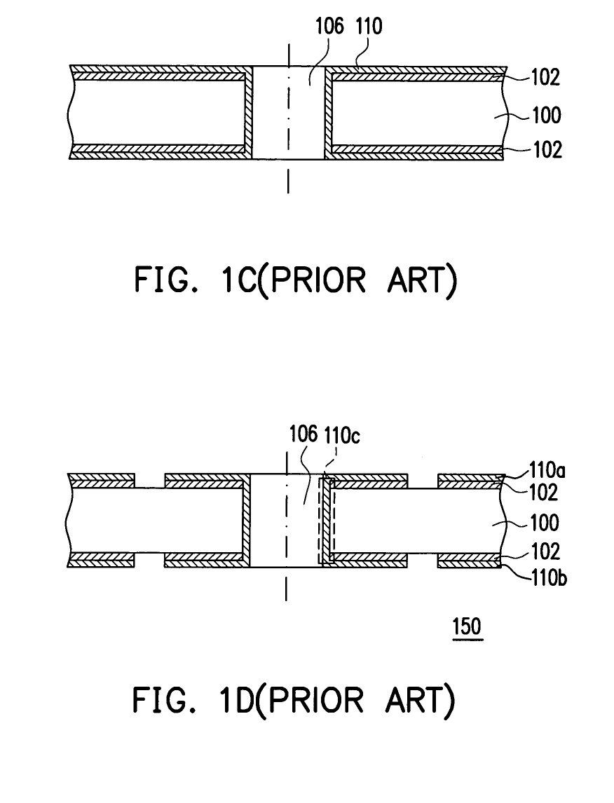

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

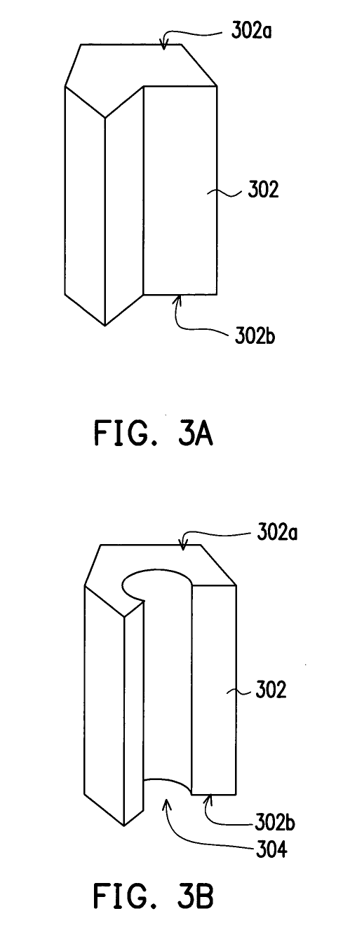

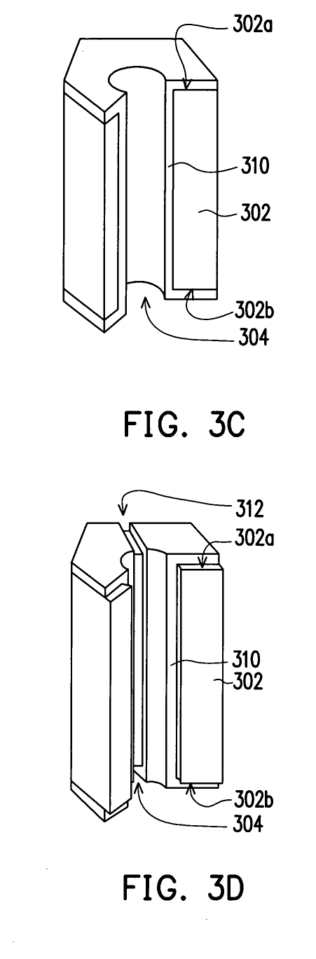

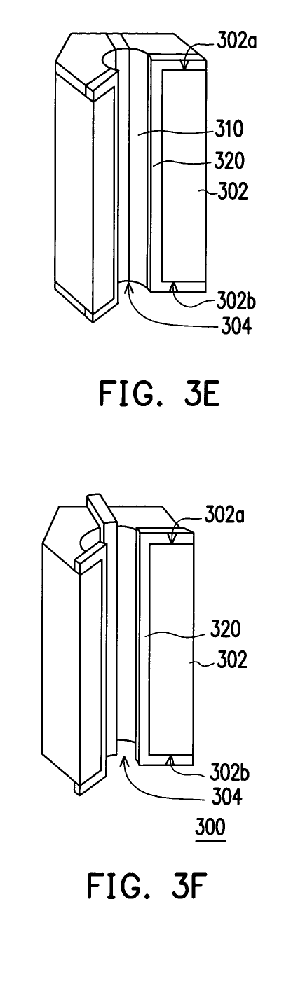

FIGS. 3A through 3F are partially cut perspective views showing the steps in a first process of plating through hole according to one embodiment of the present invention. As shown in FIG. 3A, a substrate 302 having a first surface 302a and a second surface 302b is provided. Thereafter, as shown in FIG. 3B, a through hole 304 that connects the first surface 302a and the second surface 302b is formed in the substrate 302. The method of forming the through hole 304 includes laser drilling or mechanical drilling, for example.

As shown in FIG. 3C, a photoresist layer 310 is formed over the substrate 302 to cover the inner wall of the through hole 304, the first surface 302a and the second surface 302b. The photoresist layer 310 has a high aspect ratio. The photoresist layer 310 can be formed by spin coating liquid photoresist material or performing an electro-deposition process. As shown in FIG. 3D, the photoresist layer 310 is photo-exposed and then chemically developed to form a plurality of grooves 312 in the photoresist layer 310. Each groove 312 extends from the first surface 302a to the second surface 302b through the inner wall of the through hole 304. Furthermore, each groove 312 exposes a portion of the inner wall of the through hole 304, a portion of the first surface 302a and a portion of the second surface 302b. It should be noted that the aforementioned grooves 312 could be fabricated by performing a laser ablation process or some other process as well.

As shown in FIG. 3E, conductive material (for example, copper) is deposited into the grooves 312 to form a plurality of independent conductive lines 320 by performing an electroplating process or a deposition process, for example. Each conductive line 320 extends from the first surface 302a to the second surface 302b through the inner wall of the through hole 304. Thereafter, the photoresist layer 310 is removed to form a plated through hole 300 as shown in FIG. 3F.

In the first process of plating through hole according to an embodiment of the present invention, a photolithographic process is first carried out to form a patterned photoresist layer having a plurality of grooves over a substrate with a preformed through hole. The grooves in the patterned photoresist layer extend through the same through hole. Thereafter, conductive material is deposited into the grooves by performing an electroplating or a physical or chemical deposition process to form a plurality of conductive lines. If the multiple conductive lines are formed on the same through hole by electroplating, an electroplating seed layer is preferably formed on the inner wall of the through hole and the first and second surface of the substrate prior to forming the patterned photoresist layer to facilitate the electroplating process. Furthermore, the exposed electroplating seed layer needs to be removed after removing the photoresist layer.

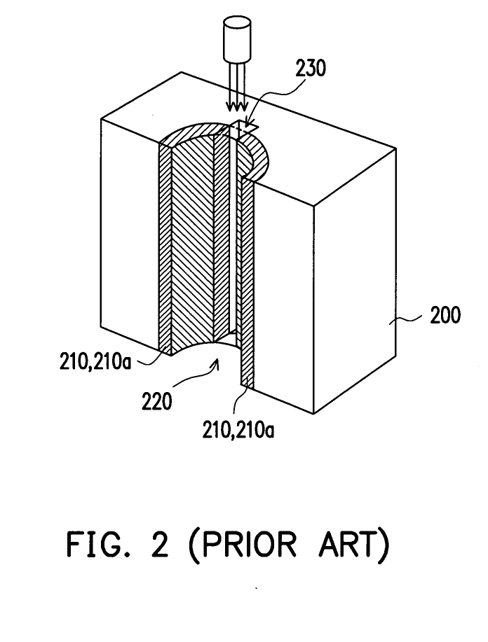

After completing the aforementioned steps, the process of fabricating through hole according to an embodiment of the present invention may further include filling the through holes with an insulation material (for example, hole plugging ink) to prevent moisture from getting inside and form undesired bridge between neighboring conductive lines. It should be noted that the insulation material could easily fill the groove between neighboring conductive lines because the pitch between conductive lines is wider (compare with the narrow groove 230 in FIG. 2). Ultimately, integrity of the through hole and overall reliability of the circuit is improved.

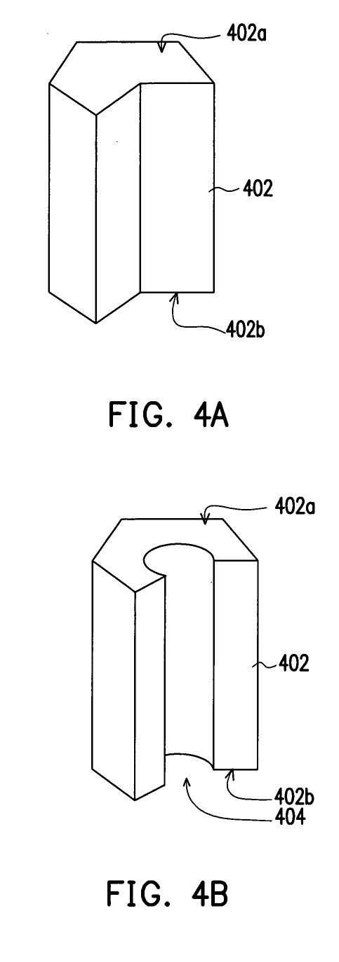

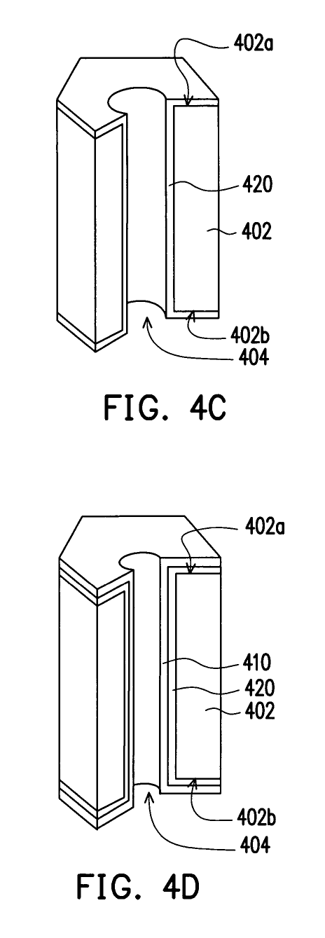

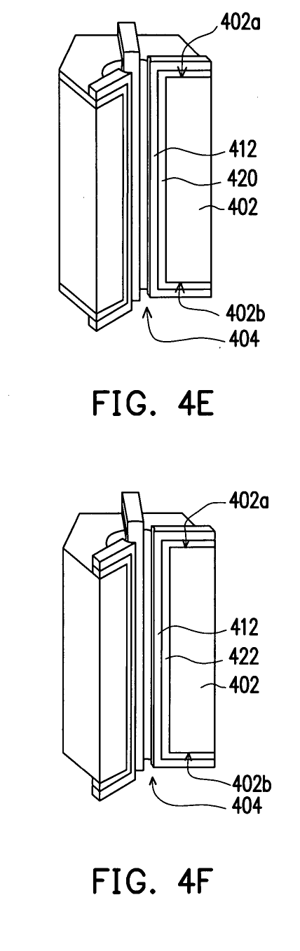

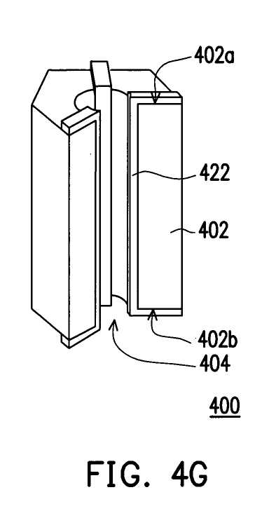

FIGS. 4A through 4G are partially cut perspective views showing the steps in a second process of plating through hole according to one embodiment of the present invention. First, as shown in FIG. 4A, a substrate 402 having a first surface 402a and a second surface 402b is provided. Thereafter, as shown in FIG. 4B, a through hole 404 that connects the first surface 402a and the second surface 402b is formed in the substrate 402. The method of forming the through hole 404 includes laser drilling or mechanical drilling, for example.

As shown in FIG. 4C, a conductive layer 420 is formed over the inner wall of the through hole 404, the first surface 402a and the second surface 402b of the substrate 402 by performing an electroplating, a physical deposition or a chemical deposition process, for example. If the conductive layer 420 is formed in an electroplating process, an electroplating seed layer (not shown) may form on the surface prior for carrying out the actual electroplating process.

As shown in FIGS. 4D and 4E, a photoresist layer 410 is formed over the entire conductive layer 420. The photoresist layer 410 is patterned to form a plurality of linear photoresist strips on the conductive layer 420, for example, by performing photo-exposure and development process. Each linear photoresist strip 412 extends from the first surface 402a to the second surface 402b through the inner wall of the through hole 404.

As shown in FIG. 4F, using the linear photoresist strips 412 as an etching mask, a portion of the exposed conductive layer 420 (as shown in FIG. 4E) is removed to form a plurality of independent conductive lines 422. If the conductive layer 420 is fabricated in an electroplating process, any exposed electroplating seed layer needs to be removed after removing the conductive layer 420 as well. Each conductive line 422 extends from the first surface 402a to the second surface 402b through the inner wall of the through hole 404. Finally, as shown in FIG. 4G, the linear photoresist strips 412 on the conductive lines 422 are removed to form a complete through hole 400 having multiple conductive lines.

In the second process of plating through hole according to an embodiment of the present invention, a conductive layer is formed over a substrate with a preformed through hole before carrying out a photolithographic/etching process to form a plurality of conductive lines passing through a single through hole. Similarly, a printing method can be deployed to fill the through hole in the substrate with an insulation material.

In summary, a high aspect ratio photoresist material together with an addition process (for example, electroplating or deposition) or a subtractive process (for example, etching) is used to form multiple conductive lines inside a single through hole in the present invention. Consequently, the present invention includes the following advantages.

1. Because the conductive lines inside a single through hole is fabricated in a photolithographic process, the process according to the present invention has a higher productivity for enhancing integrity.

2. Because a photolithographic process is capable of producing conductive lines having a greater line width and larger separation pitch inside each through hole, more circuit lines can be burnt on the substrate.

3. With a larger pitch between neighboring conductive lines inside a single through hole, the through hole is easily plugged using an insulating material. Thus, overall reliability and performance of substrate circuits are improved.

4. Unlike most conventional process that typically removes a portion of the substrate, glass fiber layer or copper layer around the through hole, the processing steps according to an embodiment of the present invention maintain the shape and integrity of the through hole. Therefore, the process in the present invention has a higher yield and product reliability.

5. Because multiple signals can be respectively transmitted through the conductive lines that pass through a single through hole, the number of through holes in the substrate can be reduced so that a smaller circuit board area is occupied. Therefore, distance between burnt circuit lines and the area for laying power or ground lines sacrificed to form the through holes can be reduced.

6. The conductive lines formed inside a single through hole can be used to transmit signals with closely related electrical attributes such as a differential pair to correspond better with a chip package using this circuit board.

7. The multi-conducting through hole may provide a guard wire function as well. That is, a guard wire such as a ground wire or a power wire may be disposed on each side of a signal line inside the same through hole to improve the electrical performance of the substrate circuit.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A process of forming a plated through hole having a plurality of conductive lines, comprising the steps of:
providing a substrate having a first surface and a second surface;
forming a through hole in the substrate, wherein the through hole connects the first surface and the second surface;
forming a photoresist layer over the substrate, wherein the photoresist layer covers the inner wall of the through hole, the first surface and the second surface;
forming a plurality of grooves in the photoresist layer, wherein each groove extends from the first surface to the second surface through the inner wall of the through hole so that a portion of the inner wall of the through hole, a portion of the first surface and a portion of the second surface are exposed;
depositing conductive material into the grooves to form a plurality of conductive lines, wherein each conductive line extends from the first surface to the second surface through the inner wall of the through hole; and
removing the photoresist layer.

2. The process of claim 1, wherein after the step of forming the through hole but before the step of forming the photoresist layer, further comprising a step of forming an electroplating seed layer over the inner wall of the through hole, the first surface and the second surface to facilitate the deposition of conductive material into the groove through an electroplating process, and a step of removing the exposed electroplating seed layer after the step of removing the photoresist layer.

3. The process of claim 1, wherein the step of depositing conductive material into the grooves comprises performing a physical deposition process or a chemical deposition process.

4. The process of claim 1, wherein the step of forming a plurality of grooves in the photoresist layer comprises performing a photo-exposure and developing the exposed photoresist layer chemically.

5. The process of claim 1, wherein the step of forming a plurality of grooves in the photoresist layer comprises performing a laser burning process.

6. The process of claim 1, further comprising a step of filling the interior of the through hole with an insulating material after the step of removing the photoresist layer.

7. A process of forming a plated through hole having multiple conductive lines, comprising the steps of:
providing a substrate having a first surface and a second surface;
forming a through hole in the substrate, wherein the through hole connects the first surface and the second surface;
forming a conductive layer over the substrate, wherein the conductive layer covers the inner wall of the through hole, the first surface and the second surface;
forming a plurality of linear photoresist strips on the conductive layer, wherein each linear photoresist strip extends from the first surface to the second surface through the inner wall of the through hole;
removing a portion of the conductive layer to form a plurality of conductive lines using the linear photoresist strips as an etching mask, wherein each conductive line extends from one surface to the second surface through the inner wall of the through hole; and
removing the linear photoresist strips.

8. The process of claim 7, wherein after the step of forming the through hole but before the step of forming the photoresist layer, further comprising a step of forming an electroplating seed layer over the inner wall of the through hole, the first surface and the second surface to facilitate the formation of the conductive layer in an electroplating process, and a step of removing the exposed electroplating seed layer in the step of forming the conductive lines.

9. The process of claim 7, wherein the step of forming a conductive layer over the inner wall of the through hole, the first surface and the second surface comprises performing a physical deposition process or a chemical deposition process.

10. The process of claim 7, wherein the step of forming a plurality of linear photoresist strips comprises:
forming a photoresist layer over the conductive layer; and
patterning the photoresist layer to form a plurality of linear photoresist strips on the conductive layer.

11. The process of claim 10, wherein the step of patterning the photoresist layer comprises performing a photo-exposure and developing the exposed photoresist layer chemically.

12. The process of claim 10, wherein the step of patterning the photoresist layer comprises performing a laser burning process.

13. The process of claim 7, wherein after removing the linear photoresist strips, further comprises filling the interior of the through hole with an insulating material.
